(19) United States
(12) Patent Application Publication
(10) Pub. No.: US 2025/0280644 A1
(43) Pub. Date: Sep. 4, 2025

(54) LIGHT-EMITTING DEVICE

(71) Applicant: NICHIA CORPORATION, Tokushima (JP)

(72) Inventor: Hiroki YUU, Anan-shi (JP)

(21) Appl. No.: 19/058,655

(22) Filed: Feb. 20, 2025

(30) Foreign Application Priority Data
Mar. 1, 2024 (JP) 2024-031352

(51) Int. Cl. H10H 29/851; H10H 29/855

(52) U.S. Cl. CPC H10H 29/8514; H10H 29/8552

(57) ABSTRACT

A light-emitting device includes: a substrate; light-emitting elements disposed on an upper surface of the substrate and configured to be individually driven; a wavelength conversion part covering upper and lateral surfaces of each of the light-emitting elements; a first light-shielding part located on a lower surface side of each of the light-emitting elements and a lower surface side of the wavelength conversion part; and a second light-shielding part. At least one groove is provided in the wavelength conversion part and the first light-shielding part such that a groove of the at least one groove is located between adjacent ones of the light-emitting elements. The second light-shielding part is provided within the at least one groove. In a cross-sectional view, a width of the second light-shielding part increases as a distance from the substrate increases, and the second light-shielding part is exposed at an upper surface of the wavelength conversion part.

### CROSS-REFERENCE TO RELATED APPLICATIONS

This application is based on and claims priority to Japanese Patent Application No. 2024-031352, filed on Mar. 1, 2024, the entire contents of which are incorporated herein by reference.

### BACKGROUND

### 1. Technical Field

The present disclosure relates to a light-emitting device.

### 2. Description of Related Art

A light-emitting device including a substrate, a light-emitting element held on the substrate, a first resin encapsulant covering the light-emitting element, and a second resin encapsulant provided on the first resin encapsulant is known. In the light-emitting device, the first resin encapsulant contains a light reflective material, and the second resin encapsulant converts a portion of first light emitted from the light-emitting element into second light having a different wavelength, and mixes the first light and the second light (see International Publication Pamphlet No. WO2013/011628, for example).

### SUMMARY

An object of an embodiment of the present disclosure is to increase a luminance difference between a turned-on light-emitting element and a turned-off light-emitting element in a light-emitting device including a plurality of light emitting elements.

A light-emitting device according to one embodiment of the present disclosure includes: a substrate having an upper surface; a plurality of light-emitting elements disposed on the upper surface of the substrate and configured to be individually driven; a wavelength conversion part covering an upper surface and a lateral surface of each of the plurality of light-emitting elements; a first light-shielding part located on a lower surface side of each of the plurality of light-emitting elements and a lower surface side of the wavelength conversion part; and a second light-shielding part, wherein at least one groove is provided in the wavelength conversion part and the first light-shielding part such that a groove of the at least one groove is located between adjacent light-emitting elements of the plurality of light-emitting elements, the second light-shielding part is provided within the at least one groove, and in a cross-sectional view, a width of the second light-shielding part increases as a distance from the substrate increases, and the second light-shielding part is exposed at an upper surface of the wavelength conversion part.

### BRIEF DESCRIPTION OF THE DRAWINGS

FIG. 1 is a perspective view schematically illustrating a light-emitting device according to an embodiment;

FIG. 2 is a perspective view schematically illustrating the light-emitting device according to the embodiment, in which some components are not depicted;

FIG. 3 is a top view schematically illustrating the light-emitting device according to the embodiment;

FIG. 4 is a cross-sectional view taken through line IV-IV of FIG. 3;

FIG. 5 is a partial enlarged view of a light-emitting element and the vicinity of the light-emitting element of FIG. 4;

FIG. 6A is a cross-sectional view illustrating a method of manufacturing a light-emitting device according to an embodiment;

FIG. 6B is a cross-sectional view illustrating the method of manufacturing the light-emitting device according to the embodiment;

FIG. 6C is a cross-sectional view illustrating the method of manufacturing the light-emitting device according to the embodiment;

FIG. 6D is a cross-sectional view illustrating the method of manufacturing the light-emitting device according to the embodiment; and

FIG. 6E is a cross-sectional view illustrating the method of manufacturing the light-emitting device according to the embodiment.

### DETAILED DESCRIPTION

A light-emitting device according to the present disclosure (hereinafter may be referred to as a “light-emitting device according to an embodiment”) will be described below with reference to the accompanying drawings. In the following description, terms indicating specific directions and positions (for example, “upper”, “upward”, “lower”, “downward”, and other terms including these terms) are used as necessary. These terms are used to facilitate understanding of the present disclosure with reference to the drawings, and the technical scope of the present disclosure is not limited by the meaning of these terms. The same reference numerals appearing in a plurality of drawings refer to the same or similar portions or members.

An embodiment to be described below exemplifies a light-emitting device to embody the technical ideas behind the present disclosure, but the present disclosure is not limited to the described embodiment. In addition, unless otherwise specified, the dimensions, materials, shapes, relative arrangements, and the like of components described in the embodiment are not intended to limit the scope of the present invention thereto, but are described as examples. The contents described in one embodiment can be applied to other embodiments and modifications. The sizes, positional relationships, and the like of members illustrated in the drawings may be exaggerated for clearer illustration. Furthermore, in order to avoid excessive complication of the drawings, a schematic view in which some elements are not illustrated may be used, or an end view illustrating only a cut surface may be used as a cross-sectional view.

### Embodiments

A light-emitting device according to certain embodiments of the present disclosure includes: a substrate having an upper surface; a plurality of light-emitting elements disposed on the upper surface of the substrate and configured to be individually driven; a wavelength conversion part covering an upper surface and lateral surfaces of each of the plurality of light-emitting elements; a first light-shielding part located on a lower surface side of each of the plurality of light-emitting elements and a lower surface side of the wavelength conversion part; and a second light-shielding part, wherein at least one groove is provided in the wavelength conversion part and the first light-shielding part such that a groove of the at least one groove is located between adjacent light-emitting elements of the plurality of light-emitting elements, the second light-shielding part is provided within the groove, and, in a cross-sectional view, a width of the second light-shielding part increases as a distance from the substrate increases, and the second light-shielding part is exposed at an upper surface of the wavelength conversion part.

### Light-Emitting Device 1

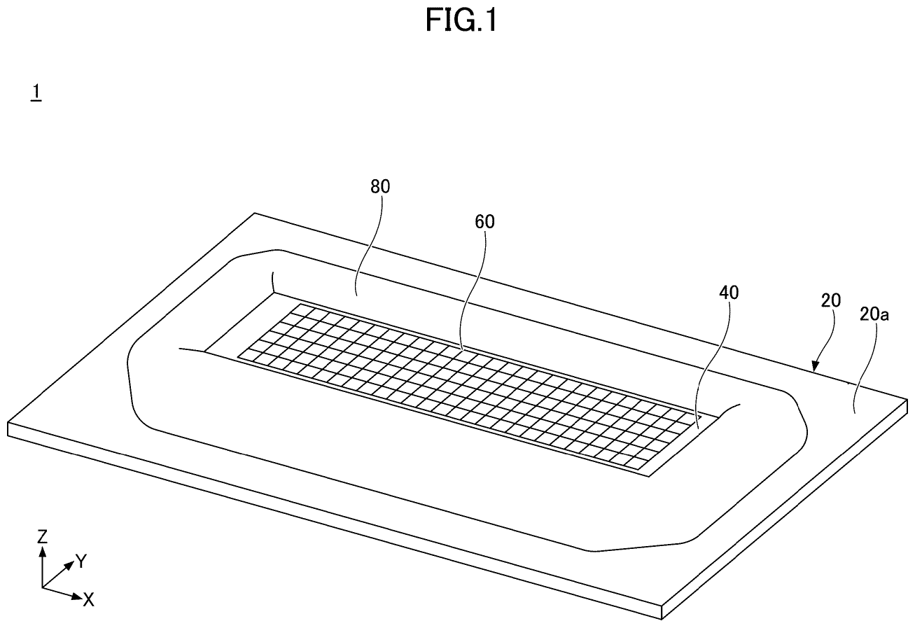

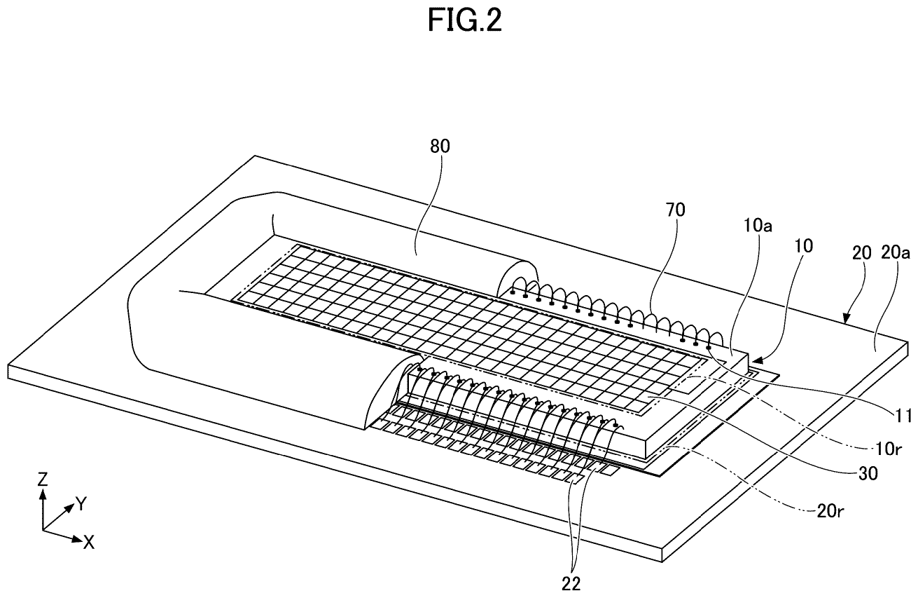

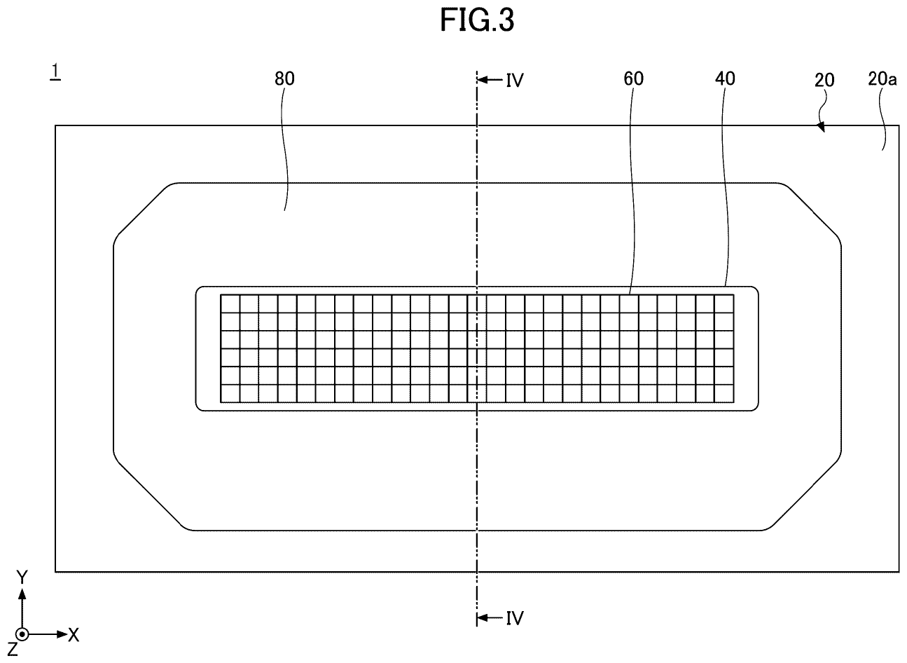

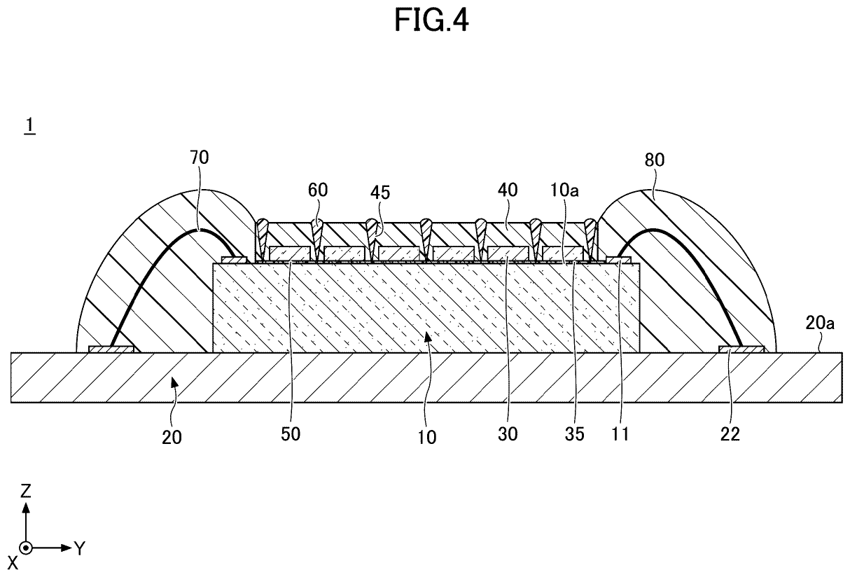

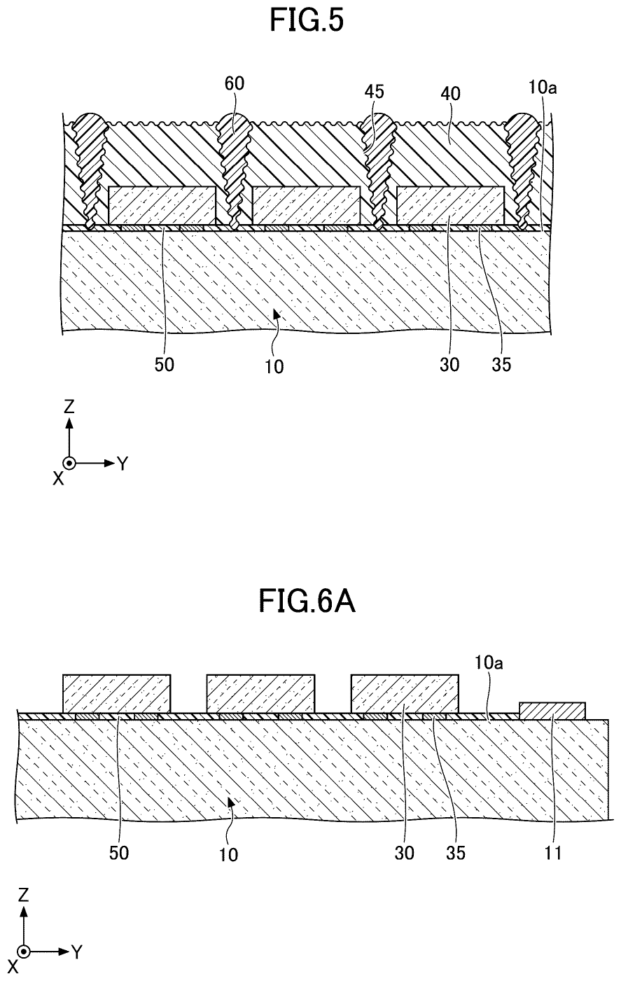

As one example of the light-emitting device according to one embodiment of the present discourse, a light-emitting device 1 will be described below. FIG. 1 is a perspective view schematically illustrating the light-emitting device according to the present embodiment. FIG. 2 is a perspective view schematically illustrating the light-emitting device according to the present embodiment, in which some components are not depicted. FIG. 3 is a top view schematically illustrating the light-emitting device according to the present embodiment. FIG. 4 is a cross-sectional view taken through line IV-IV of FIG. 3. FIG. 5 is a partial enlarged view of a light-emitting element and the vicinity of the light-emitting element of FIG. 4.

In the drawings, for reference, an X-axis, a Y-axis, and a Z-axis orthogonal to one another are illustrated as necessary. A direction parallel to the X-axis is referred to as an X direction, a direction parallel to the Y-axis is referred to as a Y direction, and a direction parallel to the Z-axis is referred to as a Z direction. Further, a direction indicated by an arrow in the X axis direction is referred to as a +X direction, and a direction opposite to the +X direction is referred to as a −X direction. A direction indicated by an arrow in the Y direction is referred to as a +Y direction, and a direction opposite to the +Y direction is referred to as a −Y direction. A direction indicated by an arrow in the Z direction is referred to as a +Z direction, and a direction opposite to the +Z direction is referred to as a −Z direction. However, these directions do not limit the orientation of the light-emitting device during use, and the light-emitting device may be oriented in any appropriate direction. Further, viewing an object from the +Z side to the −Z side is referred to as a top view.

As illustrated in FIG. 1 to FIG. 5, the light-emitting device 1 includes a substrate 10, a plurality of light-emitting elements 30, a wavelength conversion part 40, a first light-shielding part 50, and a second light-shielding part 60.

The plurality of light-emitting elements 30 are arranged on an upper surface 10a of the substrate 10. The plurality of light-emitting elements 30 can be arranged, for example, in a matrix in a top view. The plurality of light-emitting elements 30 is configured to be individually driven. The plurality of light-emitting elements 30 may be individually driven by, for example, the substrate 10 serving as a semiconductor integrated circuit substrate such as an application specific integrated circuit (ASIC), or may be individually driven by an electric circuit provided outside the light-emitting device 1.

The wavelength conversion part 40 covers the upper surface and the lateral surfaces of each of the plurality of light-emitting elements 30. The wavelength conversion part 40 is configured to convert light incident from the light-emitting elements 30 into light having a different wavelength and to emit the converted light. The wavelength conversion part 40 may emit light incident from the light-emitting elements 30 without converting a portion of the light into light having a different wavelength.

Alternatively, the wavelength conversion part 40 may convert the entirety of the light incident from the light-emitting elements 30 into light having a different wavelength and emit the light. The thicknesses from the upper surfaces of the light-emitting elements 30 to the upper surface of the wavelength conversion part 40 may be uniform or may differ among the light-emitting elements 30.

The first light-shielding part 50 is located on the lower surface side of each of the plurality of light-emitting elements 30 and the lower surface side of the wavelength conversion part 40. For example, the upper surface of the first light-shielding part 50 is in contact with the lower surface of each of the plurality of light-emitting elements 30 and the lower surface of the wavelength conversion part 40. The first light-shielding part 50 covers the lateral surfaces of electrodes 35 of the light-emitting elements 30. The first light-shielding part 50 contains, for example, a light reflecting member. The first light-shielding part 50 may contain a light absorbing member.

At least one groove 45 is provided in the wavelength conversion part 40 and the first light-shielding part 50 such that a groove 45 of the at least one groove 45 is located between adjacent light-emitting elements 30. In a cross-sectional view, the width of the groove 45 increases as the distance from the substrate 10 increases, and the groove 45 opens at the upper surface of the wavelength conversion part 40.

The second light-shielding part 60 is provided within the at least one groove 45. In a cross-sectional view, the width of the second light-shielding part 60 increases as the distance from the substrate 10 increases, and the second light-shielding part 60 is exposed at the upper surface of the wavelength conversion part 40. The second light-shielding part 60 contains, for example, a light absorbing member. The second light-shielding part 60 may contain a light reflecting member. The second light-shielding part 60 can be disposed so as to surround each of the plurality of light-emitting elements 30 in a top view, for example.

The light-emitting device 1 can further include a package substrate 20, wires 70, and a covering member 80. In the example of FIG. 1 to FIG. 5, the substrate 10 is mounted on an upper surface 20a of the package substrate 20. First terminals 11 are disposed on the upper surface 10a of the substrate 10 and located outward of a region where the plurality of light-emitting elements 30 are arranged. The package substrate 20 is larger than the substrate 10 in a top view. Second terminals 22 are disposed on the upper surface 20a of the package substrate 20 and located outward of a region where the substrate 10 is mounted. Each first terminal 11 of the substrate 10 is electrically connected to a corresponding one of the second terminals 22 of the package substrate 20 by a corresponding wire 70. The first terminals 11, the second terminals 22, and the wires 70 are covered by the covering member 80 disposed on an outer peripheral portion of the upper surface 10a of the substrate 10 and an outer peripheral portion of the upper surface 20a of the package substrate 20. The wavelength conversion part 40 can be located inward of the covering member 80 in a top view.

In FIG. 2, for convenience of illustration, the entire wavelength conversion part 40, the entire second light-shielding part 60, and a portion of the covering member 80 are not depicted so as to show the plurality of light-emitting elements 30, some wires 70, and the like.

In the light-emitting device 1, the plurality of light-emitting elements 30 can be individually driven. Thus, there is a case in which one of two adjacent light-emitting elements 30 is turned on and the other light-emitting element 30 is turned off. In this case, even when light from the turned-on light-emitting element 30 travels toward the turned-off light-emitting element 30, the light traveling toward the turned-off light-emitting element 30 is reflected and/or absorbed by the second light-shielding part 60, and thus does not reach the turned-off light-emitting element 30. Therefore, a luminance difference between the turned-on light-emitting element 30 and the turned-off light-emitting element 30 can be increased. In other words, light can be emitted without substantially causing interference of light between the adjacent light-emitting elements 30.

Further, in the light-emitting device 1, in a cross-sectional view, the width of the second light-shielding part 60 increases as the distance from the substrate 10 increases, and the second light-shielding part 60 is exposed at the upper surface of the wavelength conversion part 40. Because the width of the second light-shielding part 60 is maximized at the upper surface of the wavelength conversion part 40, the visibility of light can be improved, and a luminance difference between the turned-on light-emitting element 30 and the turned-off light-emitting element 30 can be further increased. The upper surface of the second light-shielding part 60 preferably protrudes with respect to the upper surface of the wavelength conversion part 40. This makes it possible to reflect and/or absorb light emitted from the wavelength conversion part 40 and traveling toward the adjacent light-emitting elements 30. Thus, the visibility of light can be further improved, and a luminance difference between the turned-on light-emitting element 30 and the turned-off light-emitting element 30 can be further increased.

Further, in the light-emitting device 1, the wavelength conversion part 40 covers the lateral surfaces, in addition to the upper surface, of each of the plurality of light-emitting elements 30. This allows light emitted from the lateral surfaces of the light-emitting elements 30 to propagate to the upper surface of the wavelength conversion part 40. Thus, the light extraction efficiency can be increased and the luminance of the light-emitting device 1 can be improved. The upper surface of the wavelength conversion part 40 is preferably a rough surface. This increases the light exit area of the wavelength conversion part 40, and thus the luminance of the light-emitting device 1 can be further improved. When the upper surface of the wavelength conversion part 40 is a rough surface, the surface roughness can be, for example, 1 μm or more and 4 μm or less in terms of the arithmetic average height Sa. The arithmetic average height Sa can be obtained by using VK-X200 (manufactured by KEYENCE) to measure heights from the average plane at a plurality of locations of a surface for which the arithmetic mean height Sa is to be obtained, and averaging the absolute values of the measured heights.

In the light-emitting device 1, in a case where the first light-shielding part 50 contains a light reflecting member, light emitted from the lateral surfaces of the light-emitting elements 30 and traveling downward and light emitted from the lower surfaces of the light-emitting elements 30 are reflected upward by the first light-shielding part 50. Accordingly, the luminance of the light-emitting device 1 can be improved.

Further, in the light-emitting device 1, the second light-shielding part 60 is provided within the groove 45 that is provided in the wavelength conversion part 40 and the first light-shielding part 50, and thus the second light-shielding part 60 is located at an outer peripheral portion of the interface between the wavelength conversion part 40 and the first light-shielding part 50. Accordingly, the amount of light leaking from the interface between the wavelength conversion part 40 and the first light-shielding part 50 can be reduced. In addition, as compared to when the second light-shielding part 60 is provided within the groove 45 that is provided only in the wavelength conversion part 40, the contact area between the second light-shielding part 60 and members located in the surroundings of the second light-shielding part 60 increases, and thus the adhesion between the second light-shielding part 60 and each of the wavelength conversion part 40 and first light-shielding part 50 can be improved. The surfaces of the wavelength conversion part 40 and the surfaces of the first light-shielding part 50 that define the groove 45 are preferably rough surfaces. Accordingly, the contact area between the second light-shielding part 60 and the members located in the surroundings of the second light-shielding part 60 further increases, and thus the adhesion between the second light-shielding part 60 and the wavelength conversion part 40 and first light-shielding part 50 can be improved. When the surfaces of the wavelength conversion part 40 and the surfaces of the first light-shielding part 50 defining the groove 45 are rough surfaces, the surface roughness can be, for example, 1 μm or more and 4 μm or less in terms of the arithmetic average height Sa.

Each component of the light-emitting device 1 will be described below.

### Substrate 10

The substrate 10 includes a plate-shaped support member and a conductive member disposed on the upper surface side of the support member. The upper surface 10a of the substrate 10 has an element arrangement region 10r where the plurality of light-emitting elements 30 are to be arranged, and the conductive member is disposed in the element arrangement region 10r. The substrate 10 includes a plurality of first terminals 11 arranged on the upper surface 10a located outward of the element arrangement region 10r. The first terminals 11 are electrically connected to the conductive member disposed in the element arrangement region 10r.

The substrate 10 and the element arrangement region 10r can have, for example, rectangular shapes each having long sides and short sides in a top view. For example, the plurality of light-emitting elements 30 are arranged in a matrix in the element arrangement region 10r. The plurality of light-emitting elements 30 are electrically connected to any of the first terminals 11. For example, the plurality of light-emitting elements 30 can be connected in series or in parallel to the first terminals 11 in groups of a predetermined number. The length of the long sides of the element arrangement region 10r can be, for example, 8 mm or more and 18 mm or less and the length of the short sides of the element arrangement region 10r can be, for example, 2 mm or more and 6 mm or less.

Each of the first terminals 11 has, for example, a substantially circular shape, a substantially elliptical shape, or a substantially rectangular shape. The first terminals 11 are apart from each other on the upper surface 10a of the substrate 10, and are arranged in rows along the opposing long sides of the rectangular-shaped element arrangement region 10r so as to interpose the element arrangement region 10r between the rows of the first terminals 11. An interval between adjacent first terminals 11 may be constant, but is not necessarily constant. The interval between the adjacent first terminals 11 can be, for example, 20 μm or more and 100 μm or less. One end of each wire 70 is connected to a corresponding one of the first terminals 11.

The substrate 10 is, for example, a semiconductor substrate such as silicon. A region of the upper surface 10a of the substrate 10 where no conductive member is disposed is covered by, for example, an insulating film. The conductive member may be disposed inside the support member or on the lower surface of the support member. For example, an integrated circuit substrate on which circuits for individually controlling the driving of the plurality of light-emitting elements 30 are integrated can be used as the substrate 10.

Examples of the materials of the first terminals 11 and the conductive member include metals such as Cu, Ag, Au, Al, Pt, Ti, W, Pd, Fe, or Ni and/or alloys containing at least any of these metals.

### Package Substrate 20

The package substrate 20 includes a plate-shaped base member and a conductive member disposed at least on the upper surface side of the base member. The package substrate 20 has a substrate arrangement region 20r where the substrate 10 is to be arranged on the upper surface 20a, and further includes second terminals 22 on the upper surface 20a located outward of the substrate arrangement region 20r. The substrate arrangement region 20r is a region where the substrate 10 is to be arranged. The substrate arrangement region 20r is set as a region having substantially the same area as the area of the substrate 10 in a top view. When the substrate 10 has a rectangular shape in a top view, the substrate arrangement region 20r can also have a rectangular shape. As used herein, the term “substantially the same” includes tolerances caused by a member tolerance or a mounting tolerance in an acceptable range.

Each of the second terminals 22 has, for example, a substantially circular shape, a substantially elliptical shape, or a substantially rectangular shape. The second terminals 22 are apart from each other on the upper surface 20a of the package substrate 20, and are arranged in rows along the opposing long sides of the rectangular shape so as to interpose the substrate arrangement region 20r between the rows of the second terminals 22. An interval between adjacent second terminals 22 may be constant, but is not necessarily constant. The interval between the adjacent second terminals 22 can be, for example, 20 μm or more and 100 μm or less. The other end of each wire 70 is connected to a corresponding one of the second terminals 22.

The base member of the package substrate 20 is preferably formed of a material having high heat dissipation, and is more preferably formed of a material having a high light shielding property and a high strength as the base member. Specifically, examples of the material of the base member include: metals such as Al and Cu; ceramics such as aluminum oxide, aluminum nitride, silicon nitride, and mullite; resins such as phenol resins, epoxy resins, polyimide resins, bismaleimide triazine resins (BT resins), and polyphthalamide (PPA); graphite; and composite materials of a resin and a metal or a ceramic (for example, an inlay substrate in which a metal member is embedded in a resin). The base member can be a flat base member.

Alternatively, the base may have a recess in the upper surface thereof. In this case, the package substrate 20 can have the substrate 10 arranged in the recess, with the bottom of the recess serving as the substrate arrangement region 20r.

The package substrate 20 may include a conductive member for placing the substrate 10 on the surface within the substrate arrangement region 20r.

### Light-Emitting Element

Each of the light-emitting elements 30 has, for example, a square shape with a side of 40 μm or more and 100 μm or less in a plan view. Each of the light-emitting elements 30 includes positive and negative electrodes 35 on the same surface thereof, and is flip-chip mounted on the substrate 10 with the surface on which the electrodes 35 are disposed serving as a lower surface. In this case, the upper surface opposite to the surface on which the electrodes 35 are disposed serves as a main light extraction surface of each of the light-emitting elements 30.

In the light-emitting device 1, the light-emitting elements 30 are arranged on the substrate 10 at predetermined intervals in the row and column directions. The size and the number of light-emitting elements 30 to be used can be appropriately selected in accordance with the configuration of a light-emitting device to be obtained. It is preferable to arrange a larger number of smaller light-emitting elements 30 at a high density. Accordingly, an irradiation range of light emitted from the light-emitting device 1 can be controlled with a larger number of divisions. The light-emitting device 1 having such a configuration can be used as a light source of a high-resolution lighting system. For example, the number of light-emitting elements 30 included in the light-emitting device 1 can be 1,000 or more and 100,000 or less.

The light-emitting elements 30 are, for example, light-emitting diodes. Each of the light-emitting elements 30 includes a semiconductor structure. The semiconductor structure includes an n-side semiconductor layer, a p-side semiconductor layer, and an active layer located between the n-side semiconductor layer and the p-side semiconductor layer. The active layer may be a single quantum well (SQW) structure or a multiple quantum well (MQW) structure including a plurality of well layers. The active layer is configured to emit, for example, visible light or ultraviolet light.

The semiconductor structure may include a plurality of light-emitting parts each including an n-side semiconductor layer, an active layer, and a p-side semiconductor layer. When the semiconductor structure includes a plurality of light-emitting parts, well layers in the light-emitting parts may emit light having different peak emission wavelengths or the same peak emission wavelength. The same peak emission wavelength may include a variation of approximately several nanometers. A combination of peak emission wavelengths of light from the plurality of light-emitting parts can be appropriately selected. For example, if the semiconductor structure includes two light-emitting parts, combinations of light emitted from the light-emitting parts include blue light and blue light, green light and green light, ultraviolet light and ultraviolet light, blue light and green light, blue light and ultraviolet light, green light and ultraviolet light, and the like. For example, when the semiconductor structure includes three light-emitting parts, combinations of light emitted from the light-emitting parts include blue light, green light, and red light. Each of the light-emitting parts may include one or more well layers configured to emit light with peak emission wavelengths different from those of other well layers.

For example, light-emitting elements configured to emit blue light (light having a wavelength in a range of 430 nm to 490 nm) can be used as the light-emitting elements 30. However, the emission color of the light-emitting elements 30 can be selected from any wavelength according to the application. For example, as light-emitting elements configured to emit blue light (light having a wavelength in a range of 430 nm to 490 nm) or green light (light having a wavelength in a range of 495 nm to 565 nm), light-emitting elements using nitride semiconductors (InₓAl_{y}Ga_{1-x-y}N, 0≤x, 0≤y, x+y≤1), GaP, or the like can be selected. As light-emitting elements configured to emit red light (light having a wavelength in a range of 610 nm to 700 nm), not only nitride-based semiconductor elements but also GaAlAs, AlInGaP or the like can be used.

Each of the light-emitting elements 30 is bonded to the conductive member disposed in the element arrangement region 10r of the substrate 10 by using an electrically-conductive bonding member. When the light-emitting elements 30 are flip-chip mounted on the substrate 10, a bump made of a metal material such as Au, Ag, Cu, or Al can be used as the bonding member. Further, as the bonding member, solder such as an AuSn-based alloy or an Sn-based lead-free solder can be used. Further, as the bonding member, an electrically-conductive adhesive material in which electrically-conductive particles such as metal particles are contained in a resin can be used. The light-emitting elements 30 and the substrate 10 can be bonded by plating. Examples of a plating material include Cu and Au. Further, the electrodes 35 of each of the light-emitting elements 30 and the conductive member of the substrate 10 can be in direct contact with each other without no bonding member therebetween.

### Wavelength Conversion Part

The wavelength conversion part 40 contains, for example, a resin and a phosphor. Examples of the resin include known light-transmissive resins such as silicone resins and epoxy resins. Among them, a silicone resin having high reliability (specifically, a light-transmissive resin such as a phenyl silicone resin or a dimethyl silicone resin) can be preferably used.

Examples of the phosphor include yttrium aluminum garnet based phosphors (for example, (Y, Gd)₃(Al, Ga)₅O₁₂:Ce), lutetium aluminum garnet based phosphors (for example, Lu₃(Al, Ga)₅O₁₂:Ce), terbium aluminum garnet based phosphors (for example, Tb₃(Al, Ga)₅O₁₂:Ce), CCA based phosphors (for example, Ca₁₀(PO₄)₆Cl₂:Eu), SAE based phosphors (for example, Sr₄Al₁₄O₂₅:Eu), chlorosilicate based phosphors (for example, Ca₈MgSi₄O₁₆Cl₂:Eu), silicate based phosphors (for example, (Ba, Sr, Ca, Mg)₂SiO₄:Eu), oxynitride based phosphors such as β-SiAlON based phosphors (for example, (Si, Al)₃(O, N)₄:Eu) and α-SiAlON based phosphors (for example, Ca (Si, Al)₁₂(O, N)₁₆:Eu), nitride based phosphors such as LSN based phosphors (for example, (La, Y)₃Si₆N₁₁:Ce), BSESN based phosphors (for example, (Ba, Sr)₂Si₅N₈:Eu), SLA based phosphors (for example, SrLiAl₃N₄:Eu), CASN based phosphors (for example, CaAlSiN₃:Eu), and SCASN based phosphors (for example, (Sr, Ca)AlSiN₃:Eu), fluoride based phosphors such as KSF based phosphors (for example, K₂SiF₆:Mn), KSAF based phosphors (for example, K₂ (Si₁₋ₓAlₓ) F₆₋ₓ:Mn, where x satisfies 0<x<1), and

MGF based phosphors (for example, 3.5 MgO.0.5 MgF₂.GeO₂:Mn), quantum dots having a Perovskite structure (for example, (Cs, FA, MA) (Pb, Sn) (F, Cl, Br, I)₃, where FA and MA represent formamidinium and methylammonium, respectively), II-VI quantum dots (for example, CdSe), III-V quantum dots (for example, InP), and quantum dots having a chalcopyrite structure (for example, (Ag, Cu) (In, Ga) (S, Se)₂).

In a case where the light-emitting elements 30 is configured to emit blue light, the wavelength conversion part 40 can contain, for example, a phosphor configured to be excited by blue light and to emit yellow light. In this case, examples of the phosphor contained in the wavelength conversion part 40 include yttrium aluminum garnet based phosphors (for example, (Y, Gd)₃(Al, Ga)₅O₁₂:Ce). With such a configuration, white light is obtained by mixing blue light that has passed through the wavelength conversion part 40 and yellow light emitted from the wavelength conversion part 40.

### First Light-Shielding Part

For the first light-shielding part 50, a soft resin having relatively low elasticity and good shape conformability is preferably used. As the material of the first light-shielding part 50, a resin material having good transmissivity and a good insulating property, for example, a thermosetting resin such as an epoxy resin or a silicone resin, can be suitably used. Further, the first light-shielding part 50 preferably uses a resin in which a light reflecting member is contained in a resin serving as a base material. As the light reflecting member, a light reflective substance such as titanium oxide, aluminum oxide, zinc oxide, barium carbonate, barium sulfate, boron nitride, aluminum nitride, or a glass filler can be suitably used. The first light-shielding part 50 may contain a light absorbing member. As the light absorbing member, a light absorbing substance such as a pigment, carbon black, titanium black, or graphite can be suitably used.

### Second Light-Shielding Part

Similar to the first light-shielding part 50, a soft resin having relatively low elasticity and good shape conformability is preferably used for the second light-shielding part 60. As the material of the second light-shielding part 60, a material the same as or similar to the material used for the first light-shielding part 50 described above can be used. In addition, the second light-shielding part 60 preferably uses a resin in which the light absorbing member described above is contained in a resin serving as a base material. The second light-shielding part 60 may contain the light reflecting member described above.

In a case where the upper surface of the second light-shielding part 60 protrudes from the upper surface of the wavelength conversion part 40, a protruding portion of the second light-shielding part 60 may have a shape in which the height is greatest at its center portion and gradually decreases toward its peripheral portion in a cross-sectional view. In a cross-sectional view, the ratio of the width of the protruding portion at the upper surface of the wavelength conversion part 40 to the height from a position corresponding to the upper surface of the wavelength conversion part 40 to the top of the protruding portion is preferably 1:1 or less. With such a shape, the second light-shielding part 60 is less likely to spread to the upper surface of the wavelength conversion part 40. The width of the protruding portion at the upper surface of the wavelength conversion part 40 can be, for example, approximately the same as an interval between adjacent light-emitting elements 30. The interval between the adjacent light-emitting elements 30 is, for example, approximately 5 μm to 10 μm.

### Wire

As the wires 70, a metal such as Au, Ag, Cu, Pt, or Al and/or an alloy containing at least any of these metals can be used. In particular, Au having good thermal resistance and the like is preferably used. The diameter of the wires 70 can be, for example, 15 μm or more and 50 μm or less. Each wire 70 can be disposed astride a long side of the substrate 10 having a substantially rectangular shape in a plan view, and can be disposed so as to be, for example, substantially orthogonal to the long side. Among a plurality of wires 70 arranged in a row along a long side of the substrate 10, wires 70 located around the center of the row may be disposed so as to be substantially orthogonal to the long side of the substrate 10 in a plan view as described above, and wires 70 disposed near the ends of the row may be disposed obliquely with respect to the long side of the substrate 10 in a plan view. An interval between adjacent wires 70 can be 20 μm or more and 100 μm or less.

### Covering Member

The covering member 80 is a light-shielding member located outward of the element arrangement region 10r and covering the wire 70. As an example, the covering member 80 is disposed in a frame shape in a plan view so as to cover the wires 70 and surround the element arrangement region 10r.

The covering member 80 is separated from the light-emitting elements 30 in a plan view. It is preferable that the height of the covering member 80 (that is, the distance from the upper surface 20a of the package substrate 20 to the upper surface of the covering member 80) is the highest at a location directly above the top of the wire 70. In other words, the covering member 80 is preferably disposed such that the top of the covering member 80 overlaps the top of the wire 70.

As the covering member 80, a resin containing a filler having a light shielding property can be used. Examples of the resin as a base material include a silicone resin, a modified silicone resin, an epoxy resin, a modified epoxy resin, and an acrylic resin. Examples of the filler having a light shielding property include the light reflecting member or the light absorbing member contained in the first light-shielding part 50 described above. Examples of the external color of the covering member 80 include white that exhibits good light reflectivity, black that exhibits good light absorbency, and gray that exhibits light reflectivity and light absorbency. The covering member 80 can be a member in which a plurality of resin layers are laminated. From the viewpoint of reducing deterioration of the resin due to light absorption, the covering member 80 is preferably formed of a white resin having light reflectivity on at least the outermost surface thereof.

The light-emitting device 1 having the above-described configuration can be used as a light source of an in-vehicle headlight as an example. For example, the light-emitting device 1 can be used as a light source that can select an irradiation region and irradiate the irradiation region with light, such as a headlight having an adaptive driving beam (ADB) function. In this case, in the light-emitting device 1, a luminance difference between a turned-on light-emitting element and a turned-off light-emitting element can be increased, and thus a headlight with a favorable contrast can be achieved with a single light source.

### Method of Manufacturing Light-Emitting Device 1

Manufacturing steps of a method of manufacturing a light-emitting device according to one embodiment will be described below with reference to the drawings.

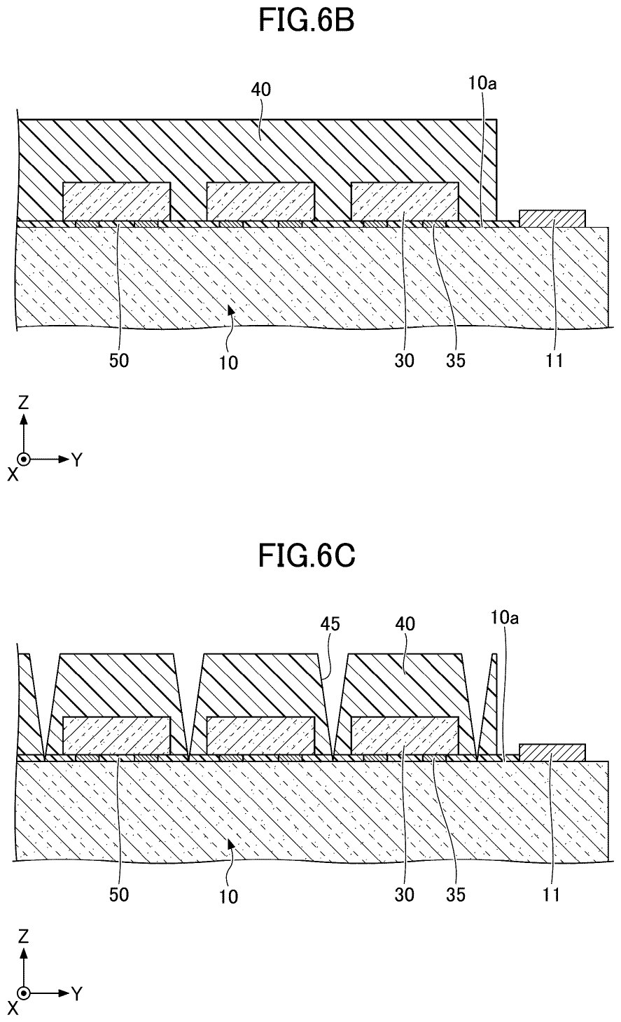

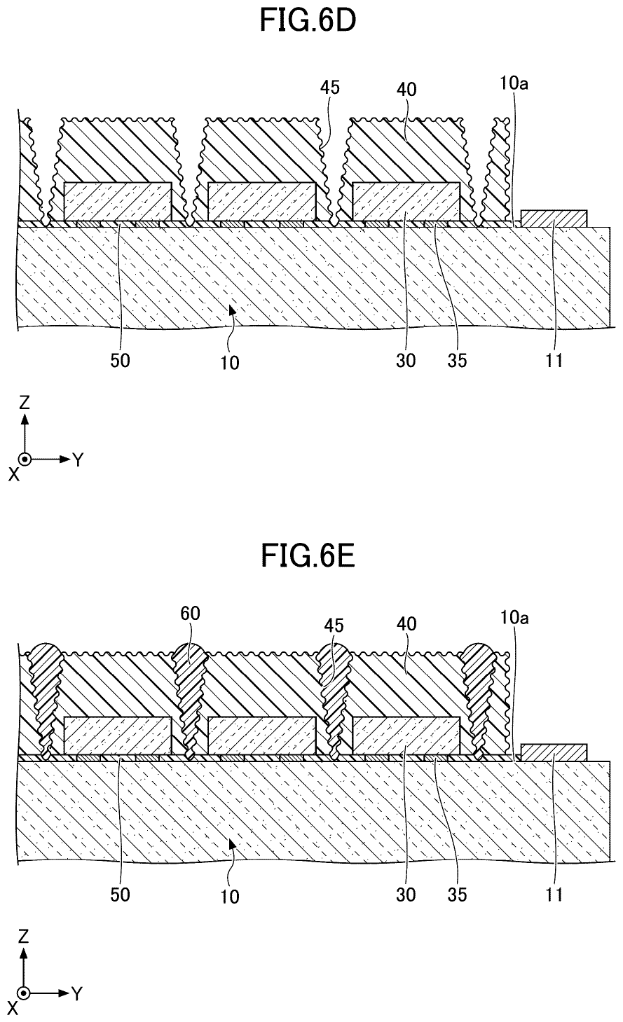

FIG. 6A to FIG. 6E are cross-sectional views illustrating the method of manufacturing the light-emitting device according to the present embodiment.

### Step of Mounting Light-Emitting Elements 30 on Substrate 10 and Disposing First Light-Shielding Part 50

As illustrated in FIG. 6A, a plurality of light-emitting elements 30 are mounted on a substrate 10, and the first light-shielding part 50 is disposed on the lower surface side of each of the light-emitting elements 30. Specifically, the substrate 10 including, on an upper surface 10a thereof, an element arrangement region 10r and first terminals 11 located outward of the element arrangement region 10r is provided. The substrate 10 can be provided by, for example, providing a flat plate-shaped support member such as silicon or the like, and forming a conductive member and the first terminal 11 by a plating method, a sputtering method, a vapor deposition method, or the like. Further, the plurality of light-emitting elements 30 are prepared. The plurality of light-emitting elements 30 can be prepared through some or all of a plurality of steps such as a step of forming a semiconductor stack and a step of forming electrodes. In the description of the manufacturing method, “providing” a member is not limited to manufacturing a member, and includes obtaining a member such as purchasing a member or inheriting a member.

Next, the light-emitting elements 30 are arranged in the element arrangement region 10r of the substrate 10. The light-emitting elements 30 can be arranged in the element arrangement region 10r of the upper surface 10a of the substrate 10 by flip-chip mounting or the like. After the light-emitting elements 30 are arranged in the element arrangement region 10r of the substrate 10, the first light-shielding part 50 is disposed between the upper surface 10a of the substrate 10 and the lower surfaces of the light-emitting elements 30. For example, after the light-emitting elements 30 are arranged on the substrate 10, a mask is disposed to cover the first terminals 11 with the element arrangement region 10r exposed from the mask. Then, the first light-shielding part 50 that is an uncured white resin or the like is disposed in a region apart from the light-emitting elements 30, and the white resin or the like is caused to flow to the lower surfaces of the light-emitting elements 30 and is cured. After the white resin is cured, the mask is removed, and the first terminals 11 are exposed through the first light-shielding part 50.

### Step of Disposing Wavelength Conversion Part 40

Next, as illustrated in FIG. 6B, a wavelength conversion part 40 is disposed on the first light-shielding part 50 that is disposed on the upper surface 10a of the substrate 10, such that the wavelength conversion part 40 covers the upper surfaces and the lateral surfaces of the light-emitting elements 30. The wavelength conversion part 40 is disposed with the first terminals 11 exposed from the wavelength conversion part 40. Specifically, for example, a member processed into a sheet shape having a predetermined size in advance is provided as the wavelength conversion part 40, and is disposed on the light-emitting elements 30. The wavelength conversion part 40 may be fixed onto the light-emitting elements 30 via a light-transmissive bonding member such as a resin, or may be fixed onto the light-emitting elements 30 by utilizing tackiness or the like of the wavelength conversion part 40 without using a bonding member. Instead of disposing a member processed into a sheet shape on the light-emitting elements 30, the wavelength conversion part 40 may be applied onto the light-emitting elements 30 by a spray or the like. Alternatively, the wavelength conversion part 40 may be formed by injection molding using a mold or the like, a transfer molding method, compression molding, or the like.

### Step of Forming Groove 45

Next, as illustrated in FIG. 6C, at least one groove 45 is formed in the wavelength conversion part 40 and the first light-shielding part 50 such that a groove 45 of the at least one groove 45 is located between adjacent light-emitting elements 30. In a cross-sectional view, the width of the groove 45 increases as the distance from the substrate 10 increases, and the groove 45 opens at the upper surface of the wavelength conversion part 40. The groove 45 having such a shape can be formed by, for example, irradiating the wavelength conversion part 40 with laser light emitted from the upper surface side of the wavelength conversion part 40. For example, an excimer laser can be used to form the groove 45. The spot diameter of the laser light on the upper surface of the wavelength conversion part 40 is, for example, 0.3 μm or more and 10 μm or less. Therefore, the groove 45 having a relatively small width can be formed. When forming a groove 45 having a relatively large width, a mechanical method such as dicing may be used.

### Roughening Upper Surface of Wavelength Conversion Part 40

Next, as illustrated in FIG. 6D, a step of roughening the upper surface of the wavelength conversion part 40 and the surfaces of the wavelength conversion part 40 and the first light-shielding part 50 defining the grooves 45 may be performed. Roughening can be performed by, for example, spraying fine particles of dry ice onto target surfaces together with compressed air. Sand blasting can also be used to perform roughening; however, in the case of sand blasting, an abrasive may remain in the surfaces of the wavelength conversion part 40 after being used, thereby causing the surfaces of the wavelength conversion part 40 to be contaminated. In contrast, in the case of using dry ice, fine particles of dry ice are vaporized and dispersed into the atmosphere, and thus an abrasive does not remain, so that the possibility that the surfaces of the wavelength conversion part 40 are contaminated can be reduced.

### Step of Disposing Second Light-Shielding Part 60

Next, as illustrated in FIG. 6E, a second light-shielding part 60 is disposed within the groove 45. The second light-shielding part 60 is formed in a shape such that, in a cross-sectional view, the width of the second light-shielding part 60 increases as the distance from the substrate 10 increases, and the second light-shielding part 60 is exposed at the upper surface of the wavelength conversion part 40. The upper surface of the second light-shielding part 60 may protrude from the upper surface of the wavelength conversion part 40. The second light-shielding part 60 can be disposed within the groove 45 by dropping an uncured resin, which serves as the second light-shielding part 60 after being cured, into the groove 45 or onto the vicinity of the groove 45 using a potting technique, for example. The uncured resin dropped onto the vicinity of the groove 45 enters the groove 45 by capillary action.

### Step of Placing Substrate 10 on Package Substrate 20

Next, a package substrate 20 including, on the upper surface 20a, a substrate arrangement region 20r where the substrate 10 is to be arranged and second terminals 22 located outward of the substrate arrangement region 20r is provided. The package substrate 20 can be provided by forming a conductive member formed of Cu or the like and the second terminals 22 on a flat plate-shaped support member formed of a metal, a ceramic, or the like by a plating method, a sputtering method, a vapor deposition method, or the like. Next, the substrate 10 on which the light-emitting elements 30 are mounted is arranged in the substrate arrangement region 20r of the package substrate 20. The substrate 10 and the package substrate 20 may be bonded to each other via a bonding member such as a sintered body containing Ag or a resin material.

### Step of Connecting Terminals by Wires 70

Next, each of the first terminals 11 of the substrate 10 and a respective one of the second terminals 22 of the package substrate 20 are connected by a respective one of wires 70. For example, each of the wires 70 is connected to a respective one of the first terminals 11 of the substrate 10, and then is connected to a respective one of the second terminals 22 of the package substrate 20. By connecting the terminals with the wires 70 in the above order, the top portions of the wires 70 can be located closer to the first terminals 11. Accordingly, the wires 70 can be arranged along a stepped portion between the substrate 10 and the package substrate 20. Accordingly, the amount of a resin disposed below the wires 70 can be reduced in a step of disposing a covering member 80 described below, and disconnection of the wires 70 due to thermal expansion of the covering member 80 can be inhibited.

### Step of Disposing Covering Member 80

Next, the covering member 80 is disposed on an outer peripheral portion of the upper surface 10a of the substrate 10 and an outer peripheral portion of the upper surface 20a of the package substrate 20 so as to cover the first terminals 11, the second terminals 22, and the wires 70. For example, the covering member 80 can be disposed by using a dispenser or the like to apply an uncured resin to a predetermined position, and curing the resin. The covering member 80 may be disposed after the wavelength conversion part 40 is disposed. A light-emitting device 1 is obtained through the above steps.

According to certain embodiments of the present disclosure, in a light-emitting device including a plurality of light emitting elements, a luminance difference between a turned-on light-emitting element and a turned-off light-emitting element can be increased.

Although certain embodiments have been described in detail above, the above-described embodiments are non-limiting examples, and various modifications and substitutions can be made to the above-described embodiments without departing from the scope described in the claims.

What is claimed is:

1. A light-emitting device comprising:
a substrate having an upper surface;
a plurality of light-emitting elements disposed on the upper surface of the substrate and configured to be individually driven;
a wavelength conversion part covering an upper surface and lateral surfaces of each of the plurality of light-emitting elements;
a first light-shielding part located on a lower surface side of each of the plurality of light-emitting elements and a lower surface side of the wavelength conversion part; and
a second light-shielding part, wherein
at least one groove is provided in the wavelength conversion part and the first light-shielding part such that a groove of the at least one groove is located between adjacent light-emitting elements of the plurality of light-emitting elements,
the second light-shielding part is provided within the at least one groove, and
in a cross-sectional view, a width of the second light-shielding part increases as a distance from the substrate increases, and the second light-shielding part is exposed at an upper surface of the wavelength conversion part.

2. The light-emitting device according to claim 1, wherein an upper surface of the second light-shielding part protrudes from the upper surface of the wavelength conversion part.

3. The light-emitting device according to claim 1, wherein the first light-shielding part contains a light reflecting member, and the second light-shielding part contains a light absorbing member.

4. The light-emitting device according to claim 1, wherein the upper surface of the wavelength conversion part is a rough surface.

5. The light-emitting device according to claim 1, wherein a surface of the wavelength conversion part and a surface of the first light-shielding part defining the at least one groove are rough surfaces.

6. The light-emitting device according to claim 1, wherein
the plurality of light-emitting elements are arranged in a matrix in a top view, and
the second light-shielding part surrounds each of the plurality of light-emitting elements in the top view.
